(19) United States
(12) Patent Application Publication
(10) Pub. No.: US 2025/0013804 A1
(43) Pub. Date: Jan. 9, 2025

(54) METHOD FOR MODELLING PRODUCTION OF CARBONATED SEDIMENTS AND THE EVOLUTION OF A SEDIMENTARY BASIN

(71) Applicant: TotalEnergies OneTech, Courbevoie (FR)

(72) Inventors: Gérard Massonnat, Pau (FR); Emmanuelle Leonforte, Pau (FR); Cédric Gal, Pau (FR)

(21) Appl. No.: 18/263,106

(22) PCT Filed: Mar. 29, 2022
(86) PCT No.: PCT/IB2022/000170

§ 371 Date: Jul. 26, 2023

(51) Int. Cl. G06F 30/27

(52) U.S. Cl. CPC G06F 30/27

(57) ABSTRACT

A computer-implemented method for modelling production of carbonated sediments in an immersed area is disclosed. The method includes a setup step comprising defining a model of said immersed area comprising a plurality of cells, at least one environmental parameter having a value in a plurality of cells of the model, at least one carbonate production model comprising a carbonated sediments production function depending on said environmental parameter, said model being applied in a plurality of cells, and at least one thermal spring having a defined localization within the model, and modelling the production of carbonated sediments originating from the carbonate production model over a period of time, wherein said modelling comprises determining an impact of the thermal spring on said environmental parameter in at least one cell of the immersed area and taking into account said impact in the production of carbonated sediments in said cell.

### BACKGROUND

### Technical Field

The present disclosure relates to a computer-implemented method for modelling production of carbonated sediments in an immersed area and the influence on said production of thermal springs. It also relates to a computer-implemented method for modelling the evolution of a sedimentary basin including at least one thermal spring.

### Description of the Related Art

Forward stratigraphic modelling is already known for modelling the formation of sedimentary basins. In this type of modelling, an area is defined as a geological gridded model, and the modelling comprises superposing layers of sediments on the gridded model, each layer corresponding to a predetermined period of time and having a thickness which depends on an amount of material brought or created at a defined location during the period of time.

It is for instance known from WO 2020/229863, WO 2020/229862, WO 2020/229866 and WO 2020/229865, methods for modelling the evolution of sedimentary basins by simulating current-induced particle transport. These methods are forward stratigraphic modelling methods enabling to model the deposition of time-layers of sediments corresponding time periods between a few 100 years and a few 10,000 years. The methods disclosed in these documents allow modelling the transport of particles based on current transport and take into account the possible interaction between several phenomena or several types of current transport.

However, these methods do not take into account the impact of immersed thermal springs on the evolution of the modelled area. A thermal spring is any discharge of deep-seated, pure or mineralized water whose temperature is higher than the local mean annual temperature of the atmosphere.

### BRIEF SUMMARY

An aim of the present disclosure is to remedy the deficiencies of the prior art. In particular, an aim of the present disclosure is to provide a method for modelling production of carbonated sediments in an immersed area, taking into account the impact on said production of one or more thermal springs.

Another aim of the present disclosure is to provide a method for modelling the evolution of sedimentary basins including one or more thermal springs.

Accordingly, a computer-implemented method for modelling production of carbonated sediments in an immersed area is disclosed, comprising:
a setup step comprising defining:
a model of said immersed area comprising a plurality of cells,
at least one environmental parameter having a value in a plurality of cells of the model,
at least one carbonate production model comprising a carbonated sediments production function depending on said environmental parameter, said model being applied in a plurality of cells, and
at least one thermal spring having a defined localization within the model, and
modelling the production of carbonated sediments originating from the carbonate production model over a period of time, wherein said modelling comprises determining an impact of the thermal spring on said environmental parameter in at least one cell of the immersed area and taking into account said impact in the production of sediments in said cell.

In embodiments, wherein defining the at least one thermal spring further comprises defining a distance of influence of the thermal spring, and determining an impact of the thermal spring on the environmental factor comprises computing a value of said environmental factor on a plurality of cells comprised between the thermal spring and said distance of influence from the thermal spring.

In embodiments, defining the at least one thermal spring further comprises setting a value of the environmental factor at the spring location and the impact of the thermal spring on the value of the environmental factor is a function of the distance.

In embodiments, the method comprises modelling a plurality of thermal springs, and computing a value of the environmental factor in a cell comprised within an area of influence of a plurality of thermal springs comprises computing a weighted mean of the value of the environmental factor impacted by each thermal spring according to the distance of the cell to the respective spring.

In embodiments, the setup further comprises associating a reference water level to the model and defining seasonal water level variations, and modeling the production of carbonated sediments over the period of time comprises:
dividing the period of time into two-subperiods comprising one subperiod in which the water level is high and one subperiod in which the water level is low,
determining for each water level a corresponding distance of influence of the thermal spring, and
for each subperiod, determining an impact of the thermal spring on the environment factor by computing a value of said environmental factor in a plurality of cells comprised between the thermal spring and the distance of influence associated to the subperiod, and modelling production of carbonated sediments during said subperiod according to said impact.

In embodiments, the environmental parameter comprises at least one of: temperature, salinity, pH, a chemical parameter.

In embodiments, the production function associated with a carbonate production model is a rate of volume or mass of produced elements during said period of time as a function of said environmental parameter.

According to another object, a computer-implemented method of modelling sedimentary deposition within an immersed area is disclosed, comprising:
a setup step comprising defining:
a model of said immersed area comprising a plurality of cells,
at least one environmental parameter having a value in a plurality of cells of the model,
at least one carbonate production model having a carbonated sediments production function depending on said environmental parameter, said model being applied in a plurality of cells,
at least one thermal spring having a defined localization within the model, and
at least one water current type occurring within the immersed area, and
simulating the evolution of the geological gridded model over a period of time, comprising:
modelling the production of carbonated sediments originating from the carbonate production model over said period of time, wherein said modelling comprises determining an impact of the thermal spring on said environmental parameter and taking into account said impact in the production of sediments,
determining a transport of at least one produced particle induced by the water current, and
updating the geological gridded model of the area according to the transport of the particle.

According to another object, it is disclosed a computer program product comprising code instructions for implementing the methods disclosed above, when it is executed by a processor.

According to another object, it is disclosed a non-transitory computer readable storage medium, having stored thereon a computer program comprising program instructions, the computer program being loadable into a processor and adapted to cause the processor to carry out, when the computer program is run by the processor, the methods disclosed above.

In embodiments, the method also comprises features according to the dependent claims.

The method allows taking into account the impact of thermal springs on the production of carbonated sediments. The method therefore also allows a more realistic simulation of the evolution of a sedimentary basin since, as a consequence to the presence of a thermal spring, the quantity and proportions of transported and deposited sediments may vary, and hence the resulting structure of the sedimentary basin.

### BRIEF DESCRIPTION OF THE SEVERAL VIEWS OF THE DRAWINGS

The present disclosure is illustrated by way of example, and not by way of limitation, in the figures of the accompanying drawings, in which like reference numerals refer to similar elements and in which:

FIG. 1 is a flow chart describing a possible embodiment of a method for modelling production of carbonated sediments in an immersed area,

FIG. 2a is a flow chart describing a possible embodiment of a method for modelling sedimentary deposition within an immersed area,

FIG. 2b is a flow chart describing another possible embodiment of a method for modelling sedimentary deposition within an immersed area,

FIG. 3a represents the distance of influence of a thermal spring,

FIG. 3b represents the distance of influence of a thermal spring for immersed area including seasonal water level variations,

FIG. 4 represents a non-limiting example of two carbonate production models,

FIG. 5a represents the evolution with time of a sedimentary basin including activity of a thermal spring during part of the period covered by the simulation,

FIG. 5b represents the evolution with time of the water pH in the sedimentary basin of FIG. 4a as a consequence of thermal spring activity,

FIG. 6 is a possible embodiment for a device that can implemented the methods disclosed below, and

FIG. 7 represents an exemplary decomposition of the column of water above ground surface into three water layers comprising a plume, a subsurface and a bottom layer.

### DETAILED DESCRIPTION

Methods for modelling the production of carbonated sediments in an immersed area, as impacted by the presence of one or more thermal springs, and methods for modelling sedimentary deposition within an immersed area including one or more thermal springs will now be described with reference to the drawings.

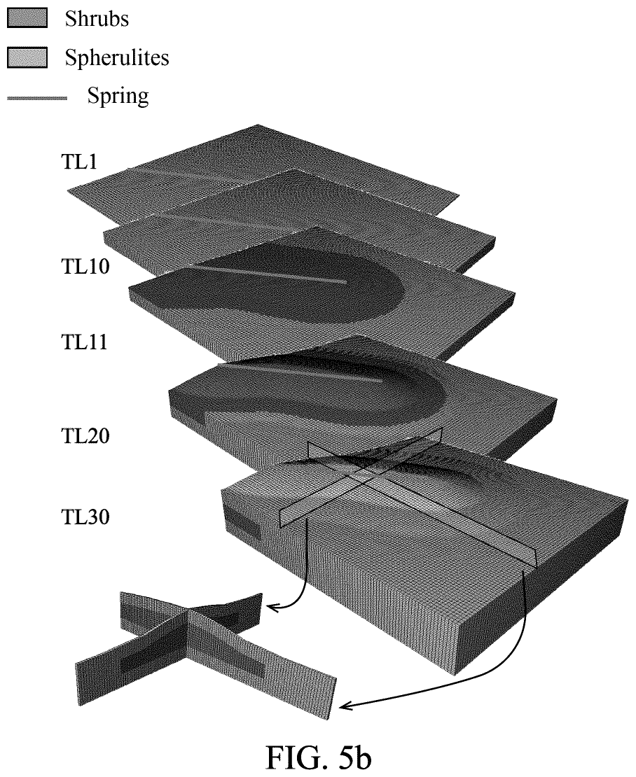

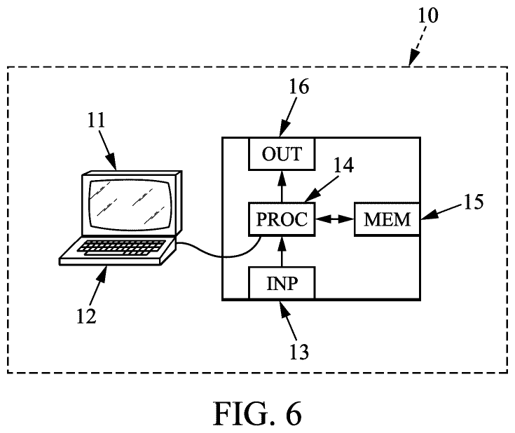

In FIG. 5, is schematically shown a possible embodiment for a computing device 10 configured for implementing these methods.

The computing device 10 can comprise one or more computer, comprising a memory 15 to store program instructions loadable into a circuit and adapted to cause circuit 14 to carry out the steps of the present disclosure when the program instructions are run by the circuit 14.

The memory 15 may also store data and useful information for carrying the steps of the present disclosure as described above.

The circuit 14 may be for instance:
a processor or a processing unit adapted to interpret instructions in a computer language, the processor or the processing unit may comprise, may be associated with or be attached to a memory comprising the instructions, or
the association of a processor/processing unit and a memory, the processor or the processing unit adapted to interpret instructions in a computer language, the memory comprising said instructions, or
an electronic card wherein the steps of the present disclosure are described within silicon, or
a programmable electronic chip such as a FPGA chip (for «Field-Programmable Gate Array»).

This computer comprises an input interface 13 for the reception of several data used for the above method according to the present disclosure, for instance the gridded model, the parameters defining the thermal springs as well as the carbonate production models, some parameters of the topography of the modelled area, some parameters of the modelled currents, etc. This computer also comprises an output interface 16 for outputting the updated geological gridded model.

To ease the interaction with the computer, a screen 11 and a keyboard 12 or a tactile screen may be provided and connected to the computer circuit 14. The various components described above may be remotely connected to one another, i.e., the memory storing the data and/or the circuit implementing the method may be remotely located with reference to the user and accessible through any suitable network.

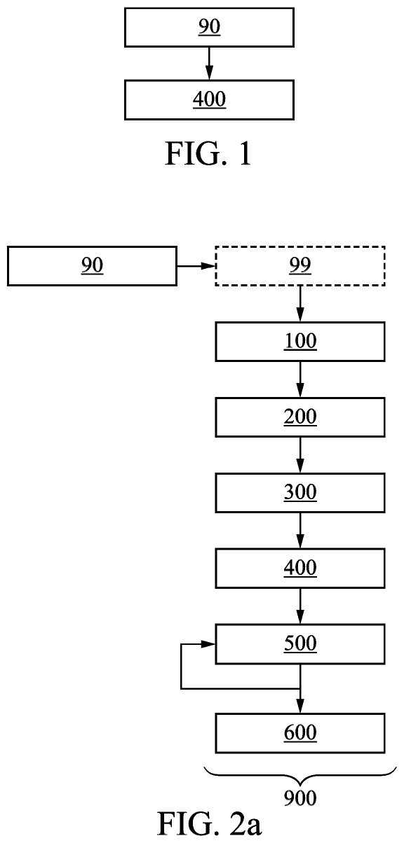

The methods described below model the impact of thermal springs on production of carbonated sediments as well as on their transport and deposition in a sedimentary area. The immersed area may be an oceanic area or a lacustrine area. The method for simulating sedimentary deposition within an immersed area is a forward stratigraphic modelling method, modelling the evolution of an immersed sedimentary area through the deposition of successive layers of sediments. Accordingly, the sedimentary area is formed by a stack of layers, wherein each layer is defined by a two-dimensional surface representing the surface of the ground of the immersed area at the time of deposition of sediments, and by a thickness of sediments forming said layer. Each layer is gridded and comprises, like in the example shown in FIG. 1, a plurality of grid cells M1,1, M1,2, M2,1, . . . , and more generally Mi,j, where the variables i and j indicate the positions of the cells within the surface. Each layer if further associated to a time t corresponding to a time of deposition of sediments. Accordingly, each cell of the modelled area can be described by three parameters (i, j, k) or (x,y,t) wherein the two first coordinates represent the location of the cell within the surface and k represents the time layer or t represents the time of formation of the surface, which is equivalent.

Typically, each cell represents an area having a side length of a few hundreds of meters, up to a few kilometers. The method starts with an initial topography corresponding to an initial surface representing the bottom of the immersed area, above which a column of water of defined height (i.e., water depth of each cell of the model) is defined, and comprises iterating a series of steps modelling the introduction into the model of clastic and/or carbonates particles during a predetermined period of time T, their transport induced by water currents during this period of time T, and the deposition of some of these particles to form an additional layer of sediments.

At the end of this period of time T, the topography of the model is updated in each cell according to the quantity of deposited particles. More specifically, a layer is generated, which thickness in each cell is determined based on a number of particles deposited at this cell. Such a layer is called a time layer since it corresponds to the passage of the predetermined period of time T. The topography of the geological gridded model of the area thus evolves with the accumulation of time layers.

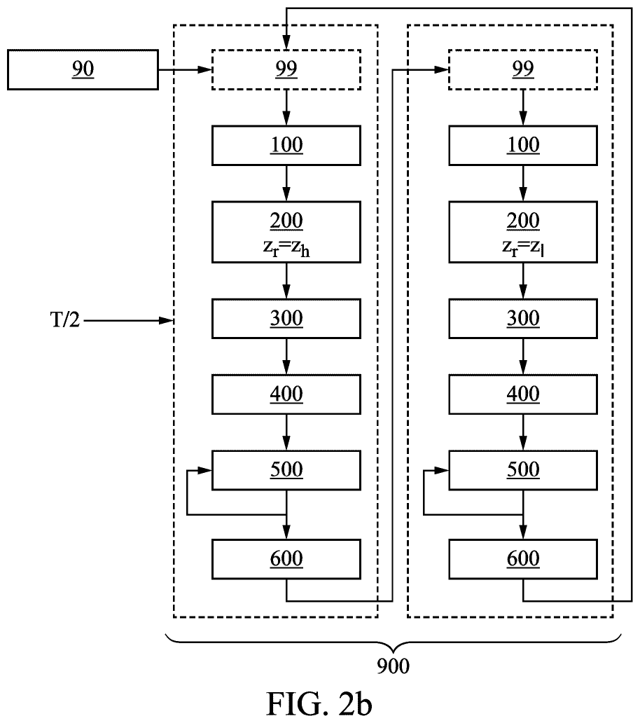

With reference to FIGS. 2a and 2b, the main steps of a method for modelling sedimentary deposition within an immersed area, according to two different embodiments, will now be disclosed. Among them, the main steps of the method for modelling production of carbonated sediments are shown in FIG. 1.

### Setup Step

The method for modelling the evolution of a sedimentary area comprises a first preliminary setup step 90.

The setup step comprises initializing a topography of the modelled area, i.e., receiving an initial surface having a plurality of cells wherein each cell corresponds to a position (x,y) and is assigned a parameter z0 which is the height of said bottom surface.

The setup step also comprises setting an initial reference water level zᵣ, as well as the evolution of the reference water level over the model between two successive periods of time T, i.e., two successive time layers (eustatism for marine areas) and the amount of subsidence of the ground's surface over the geological gridded model between two time layers. The amount of subsidence may vary over the model of the area, i.e., it may not be the same for all the cells of the models.

From the initial topography of the geological gridded model and the initial reference water level, a water depth WD in each cell is inferred and assigned to the respective cell. If the height z0 of a cell is above the reference water level zr, then the water depth is zero. It can be understood that as the method aims at modelling the formation of a sedimentary area, at least some of the cells of the initial topography are below water level, i.e., z₀<zᵣ.

When the sedimentary area is a lacustrine area, the setup step may also comprise defining respectively high and low reference water levels zᵣₕ and zᵣₗ rendering the seasonal variations of the water level of the lake. In this case, and as indicated in more details below, the period of time T during which carbonated sediments production, transport and deposition are modelled is divided into two equal subperiods and the water depth WD in each cell is computed for each subperiod.

The setup step 90 also includes defining at least one environmental parameter having a value in a plurality of cells of the model. The environmental parameter may be chosen among temperature, salinity, pH, or a user-defined chemical parameter of the water such as the concentration of a determined chemical species. The environmental parameter may be set as having a single value over all the simulated area, or the user may define locations and respective values of the environmental parameter.

The setup step also includes defining at least one thermal spring within the immersed area, the thermal spring having a determined location defined by one or several cells of the area. In an embodiment, the user may define the specific location of the thermal spring by setting one or more cells of the area corresponding to said location. In another embodiment, a number of thermal springs may be randomly distributed over a region of the immersed area that is defined by the user.

Furthermore, to each thermal spring is associated at least one environmental parameter that is locally modified due to the thermal spring, as well as a value of said environmental parameter at the thermal spring. Said at least one environmental parameter is chosen among the environmental parameters defined above. A distance of influence d_{spring,max} is also defined in association to each thermal spring. When high and low reference water levels are defined, respective distances of influence may be defined in association with each reference water level.

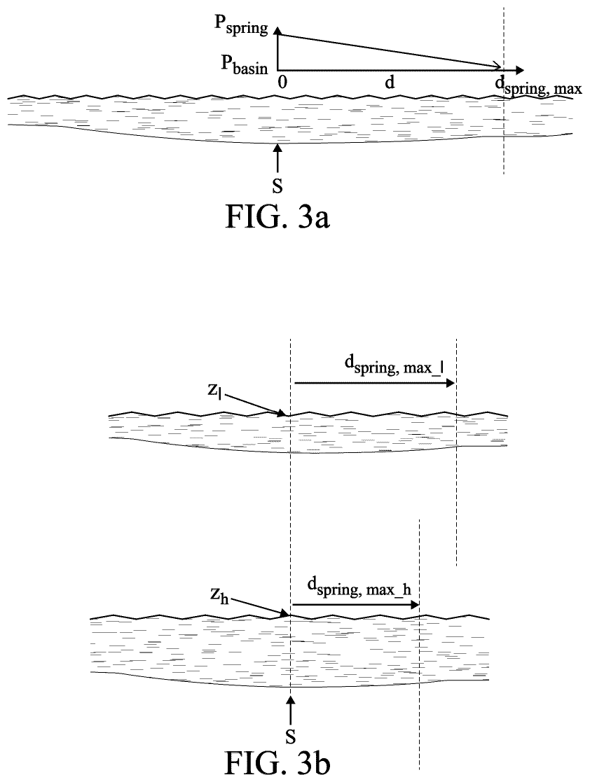

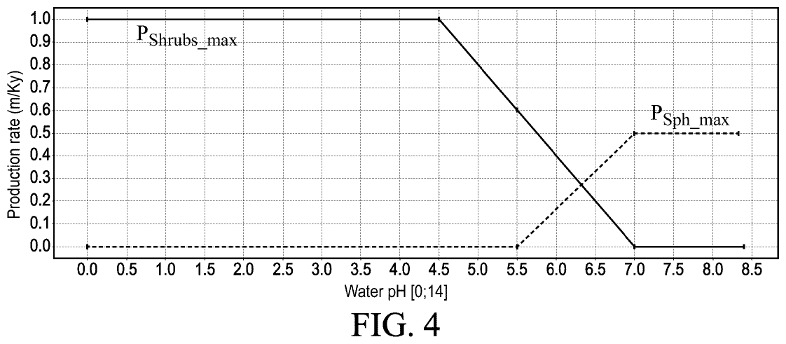

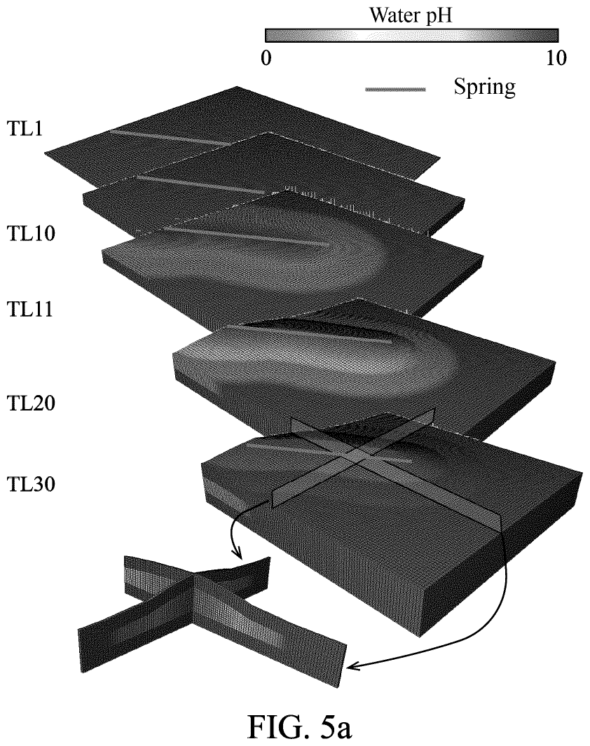

With reference to FIG. 3a, the environmental parameter that is impacted by the presence of the thermal spring exhibits a set value P_{spring} at the location of the thermal spring, and the value of the environmental parameter then varies linearly with the distance to the thermal spring until reaching the value defined for the area or a region thereof, denoted P_{basin} in cells located at the distance of influence or further from the thermal spring S.

With reference to FIG. 3b, the same applies when two distances of influence d_{spring,max_h} and d_{spring,max_l} are defined corresponding to respectively high (zₕ) and low (zₗ) water levels. The value of the environmental parameter at the location of the thermal spring may be the same for both water levels, but the linear variation of the values of the environmental parameter with distance then varies according to the distance of influence.

Then if an environmental parameter is influenced by a plurality of thermal springs, its value in a cell may be computed as a weighted mean of the value of the environmental factor impacted by each thermal spring according to the distance of the cell to the respective spring:

$$P ( x , y ) = \frac{{\sum }_{i} {P}_{i} ( x , y ) . {D}_{i} ( x , y )}{{\sum }_{i} {D}_{i} ( x , y )}$$

Where P is the value of an environmental parameter in a cell, Pi is the value of the environmental parameter as influenced by the spring i, and Di is defined as follows:

$${D}_{i} ( x , y ) = max ( 0 , 1 - ( \frac{{d}_{spring} ( x , y )}{{d}_{spring , max}} ) )$$

Where d_{spring} is the distance of the cell from the spring i, and d_{spring,max} is the distance of influence of spring i.

The setup step 90 also includes the user defining at least one carbonate production model, said model comprising a carbonated sediments production function depending on at least one environmental parameter.

For a given carbonate production model, the carbonated sediments production function defines a quantity of produced carbonates according to time, said quantity being expressed in volume, in mass or as a height of produced sediments per cell, which also corresponds to a volume since the area of a cell is known. The quantity of sediments produced according to time may be influenced by one or several environmental parameters among those defined above such as pH, water temperature, salinity, etc.

For instance, a maximum production rate may be defined for a range of values of one or more environmental parameter, and at least one lower production rate may be defined for other ranges of values of the environmental parameter.

For purposes of illustration only, two exemplary carbonated sediments production functions are shown in FIG. 5, including a shrubs production model, said model being associated with a production function that is:
maximum (P_{Shrubs_max}) for a water pH below 4.5,
null for a water pH above 7, and
that decreases linearly between 4.5 and 7.

In the same figure, a spherulite production model is defined, said model being also associated with a production function that depends on water pH and which is:
null for a water pH below 5.5
maximum (P_{Sph_max}) for a water pH above 7, and
that increases linearly between 5.5 and 7.

The parameterization of production of carbonates also comprises defining for each carbonate production model a sedimentary element type, and granulometry of the produced sediments.

The user may also define one or more siliciclastic supply processes such as river mouth supply or volcano supply. In this case, the parameterization of each siliciclastic supply process may comprise defining a location of the source of elements (location of the volcano, river mouth, etc.), sedimentary element type, granulometry, and rate of supply of the considered process, i.e., a volume or mass of supplied sedimentary elements per time unit.

During the subsequent modelling of the supply or production processes, the sedimentary elements are introduced in the model as particles where each particle represents a determined mass or volume of siliciclastic or carbonated sediments of a defined granulometric class.

The setup step may also comprise defining and parameterizing one or more currents to be modelled, among the following water currents:
wind-induced current, including wind-induced wave current and oceanic surface current,
tidal current, and
river-mouth induced current.

Oceanic surface current can only apply for marine areas, whereas the other currents, including tidal current, can apply for both marine and lake areas. If at least one river mouth induced current is to be modelled, the setup step 90 can comprise the user setting the volumetric flow of the river at the river mouth, the width and depth of the river mouth.

The method for modelling sedimentary deposition within an immersed area then comprises a series of steps which are detailed below, and which are implemented to generate one time layer, representing the passage of the predetermined period of time T. The duration of the period of time T may also be set by the user during the setup step. Preferably, this duration may be comprised between 1,000 and 100,000 years.

As indicated above, and with reference to FIG. 2b, when the immersed area corresponds to a lacustrine area, respectively high and low water levels are defined in order to render seasonal variations of the height of the lake. In this case, the simulation of the period of time T and the generation of the time layer corresponding to this period of time is subdivided into two periods of time, the sum of which corresponding to the T, wherein the first period of time is implemented with the high-water level and the second period of time is implemented with the low-water level. The generation of a time layer corresponding to the period T then involves the series of steps twice, where each iteration allows generating a sub-time layer representing half the period of time T.

### Computation Layer

An optional preliminary step 99 implemented before each iteration of a computation layer 900 may comprise the change of some parameters of the model by the user, if it is desired to represent an evolution of these parameters between one period of time represented by a time layer T and another. For instance, the parameters regarding the river mouth current that can be set at step 90 (volumetric flow, width and height at the river mouth) may be modified at step 99. Also, the parameterization of each supply or carbonate production model may be changed at optional step 99. The eustatism and subsidence rate may also be amended between two time-layers during said preliminary step.

Step 100 comprises receiving the geological model of the area, either by loading an initial version of the model, or by updating the model according to a previous iteration of the series of steps 900. The update comprises updating a height along z of each cell, which corresponds to the initial position z0 of the cell along z added to the thickness of the sediment particles deposited at the cell. The height along z may also take into account local subsidence of the ground's surface.

The method then comprises a step 200 of computing, from the topography updated at step 100, topographic slopes of the ground surface formed by the model and inferring, from the topography and reference water level zr, the water depth WD in each cell. If the area is a lacustrine area, then the series of steps forming a computation layer 900 is implemented twice to simulate the period of time T and during a first iteration of step 200, the reference water level may be set as the high—respectively low—water level of the lake, and during the second iteration of step 200, the reference water level is set as the low—respectively high—water level of the lake.

The method may then comprise a step 300 of modelling water currents occurring over the immersed area represented by the gridded model. This step is performed by determining, for a plurality of cells of the gridded model for which WD>0, and preferably each cell for which WD>0, a direction and velocity of each water current to be modelled. The shoreline SL is defined by cells for which WD=0 and which are adjacent cells for which WD>0.

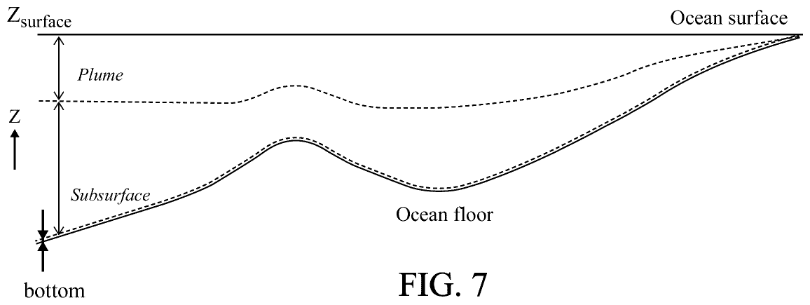

For the computation of direction and velocity of each water current, and with reference to FIG. 7, the extent of water extending over the ground surface is decomposed into three water layers of respective depths, comprising a bottom layer, extending at water bottom, a plume layer extending at water surface, and a subsurface layer extending between the plume layer and the bottom layer.

The implementation of the step of modelling the water currents then depends on the number of type of water currents that are modelled. One can refer to WO 2020/229862 for an example of detailed definition of the plume, subsurface and bottom layers, and an example of detailed implementation of the modelling of water currents. This step is not implemented if no water current is modelled.

The method further comprises a step 400 of introducing at least one particle of sediments in at least one cell of the geological gridded model, which comprises modelling the production of carbonated sediments by implementing at least the carbonate production model(s) and optionally modelling the supply of siliciclastic sediments if siliciclastic supply process(es) have been defined in the setup step.

Modelling the production of carbonated sediments comprises computing, for a plurality of cells of the model, possibly for each cell of the model, the production rate for the considered period of time T, taking into account the localization of the cell relative to thermal springs and their impact on the production of sediments. As detailed above, the proximity of a cell relative to a thermal spring may diminish or increase the production rate of a given carbonate type in a cell. Once the production rate associated is determined in a cell, step 400 comprises introducing the corresponding quantity of sediments in the cell. The carbonated sediments are produced in the bottom layer of the water.

If the immersed area is a lacustrine area and a period of time is simulated by iterating twice the series of steps 900 for rendering the seasonal variations of the lake, then for the implementation of step 400 the distance of influence of the spring is selected in accordance with the water level of the lake implemented during the same implementation of the series of steps 900.

A step 500 then comprises determining the transport of at least one produced particle of sediments induced by the modelled water current(s). The transport of a particle may comprise displacing a particle from a cell to a neighbouring cell and/or depositing the particle.

An example of detailed implementation of this step may also be found in WO 2020/229862.

The transporting step 500 is iterated until all particles introduced at the previous step are either deposited or have exited the model. If no water current is model, then step 500 only comprises depositing the sediments that have been produced at the preceding step.

During a step 600 the topography of the geological model of the area is updated to take into account the sediments deposited at the end of step 500. Step 600 may also update the topography according to eustatism and subsidence, i.e., respectively the reference water level and the ground level, by updating the height along z of each cell and the water depth of each cell.

With reference to FIGS. 5a and 5b is shown an exemplary implementation of the above-described method, showing the impact of thermal spring (in this example the thermal spring is an underwater fault modelled as a straight line) on the water pH of the neighboring cells, in FIG. 5a, and its consequences on the local production of shrubs and spherulite carbonates. Each representation of the modelled area corresponds to a respective time layer, with the number of the time layer being denoted on the side. In this example the thermal spring is modelled to have an activity only between time layer 10 and time layer 30, i.e., between the 10^{th} and 30^{th} iterations of step 900 disclosed above. One can notice that the thermal springs lowers the pH of water, which impairs the local production of spherulites during the spring's activity but boosts the production of shrubs. The impact of the presence and activity of the thermal spring results in a modification in the deposition of sediments which can be observed from the sectional views that are displayed for time layer 30.

Accordingly, the above-disclosed model helps geologists understanding the composition of the subsoil and modelling hypothesis regarding position, duration and impact of thermal springs in order to evaluate their impact in the process of sedimentary deposition.

The various embodiments described above can be combined to provide further embodiments. All of the patents, applications, and publications referred to in this specification and/or listed in the Application Data Sheet are incorporated herein by reference, in their entirety. Aspects of the embodiments can be modified, if necessary to employ concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. A computer-implemented method for modelling a production of carbonated sediments in an immersed area, comprising:
a setup, comprising defining:
a model of said immersed area comprising a plurality of cells;
at least one environmental parameter having a value in a plurality of cells of the model;
at least one carbonate production model comprising a carbonated sediments production function depending on said environmental parameter, said model being applied in a plurality of cells; and
at least one thermal spring having a defined localization within the model; and
modelling the production of carbonated sediments originating from the carbonate production model over a period of time, wherein said modelling comprises determining an impact of the thermal spring on said environmental parameter in at least one cell of the immersed area and taking into account said impact in the production of carbonated sediments in said cell.

2. The method according to claim 1, wherein defining the at least one thermal spring further comprises defining a distance of influence of the thermal spring, and determining an impact of the thermal spring on the environmental factor comprises computing a value of said environmental factor on a plurality of cells comprised between the thermal spring and said distance of influence of the thermal spring.

3. The method according to claim 2, wherein defining the at least one thermal spring further comprises setting a value of the environmental factor at a location of the thermal spring and the impact of the thermal spring on the value of the environmental factor is a function of the distance of influence.

4. The method according to claim 2, comprising modelling a plurality of thermal springs, and wherein computing a value of the environmental factor in a cell comprised within an area of influence of a plurality of thermal springs comprises computing a weighted mean of the value of the environmental factor impacted by each respective thermal spring according to the distance of the cell to the respective spring.

5. A method according to claim 1, wherein the setup further comprises associating a reference water level with the model and defining seasonal water level variations, and modeling the production of carbonated sediments over the period of time comprises:
dividing the period of time into two subperiods comprising one subperiod in which the water level is high and one subperiod in which the water level is low;
determining for each water level a corresponding distance of influence of the thermal spring; and
for each subperiod, determining an impact of the thermal spring on the environment factor by computing a value of said environmental factor in a plurality of cells comprised between the thermal spring and the distance of influence associated with the subperiod, and modelling the production of carbonated sediments during said subperiod according to said impact.

6. A method according to claim 1, wherein the environmental parameter comprises at least one of: temperature, salinity, pH, a chemical parameter.

7. A method according to claim 1, wherein the carbonated sediments production function associated with the carbonate production model is a rate of volume or mass of produced elements during said period of time as a function of said environmental parameter.

8. A computer-implemented method of modelling sedimentary deposition within an immersed area, comprising:
a setup, comprising defining:
a model of said immersed area comprising a plurality of cells;
at least one environmental parameter having a value in a plurality of cells of the model;
at least one carbonate production model having a carbonated sediments production function depending on said environmental parameter, said model being applied in a plurality of cells;
at least one thermal spring having a defined localization within the model; and
at least one water current occurring within the immersed area; and
simulating an evolution of a geological gridded model over a period of time, comprising:
modelling a production of carbonated sediments originating from the carbonate production model over said period of time, wherein said modelling comprises determining an impact of the thermal spring on said environmental parameter and taking into account said impact in the production of carbonated sediments;
determining a transport of at least one produced particle induced by the water current; and
updating the geological gridded model of the immersed area according to the transport of the at least one produced particle.

9. (canceled)

10. A non-transitory computer readable storage medium,
having stored thereon a computer program comprising program instructions, the computer program being loadable into a processor and adapted to cause the processor to carry out, when the computer program is run by the processor, the method according to claim 1.

11. A computer, configured for implementing the method according to claim 1.
